(19) United States
(12) Patent Application Publication
(10) Pub. No.: US 2013/0270536 A1
(43) Pub. Date: Oct. 17, 2013

(54) ELECTRONIC COMPONENT AND METHOD FOR PRODUCING AN ELECTRONIC COMPONENT

(71) Applicant: Daniel Steffen Setz, Muenchen (DE)

(72) Inventor: Daniel Steffen Setz, Muenchen (DE)

(73) Assignee: OSRAM OPTO SEMICONDUCTORS GMBH, Regensburg (DE)

(21) Appl. No.: 13/881,761

(22) PCT Filed: Oct. 10, 2011
(86) PCT No.: PCT/EP11/67643

§ 371 Date: Jul. 2, 2013

(30) Foreign Application Priority Data
Oct. 27, 2010 (DE) 10 2010 042 982.1

(51) Int. Cl. H01L 51/52; H01L 51/56

(52) U.S. Cl. CPC H01L 51/5271; H01L 51/56
USPC 257/40; 257/98; 438/29

(57) ABSTRACT

In various exemplary embodiments, an electronic component comprises a first electrode; an organic functional layer structure on or above the first electrode; a second electrode on or above the organic functional layer structure; a dielectric layer on or above the second electrode; and a reflection layer structure on or above the dielectric layer.

The invention relates to an electronic component and a method for producing an electronic component.

An organic light-emitting diode having two microcavities optically coupled to one another (coupled microcavities) is described in M. Mazzeo et al., Shaping white light through electroluminescent fully organic coupled-microcavities, Advanced Materials, Doi10.1002/adma.201001631, September 2010. With the aid of the second microcavity in addition to the microcavity that is customary anyway, formed by an organic light-emitting diode (OLED), it is possible to influence the emission spectrum of an OLED, as a result of which, in particular, a high color rendering index can be achieved. Said additional microcavity is formed by a transparent, organic layer, arranged between two metallic mirrors, wherein the mirror situated between the two microcavities is semitransparent, thus resulting in an optical coupling between the two microcavities.

The inventor has ascertained that such an OLED having two microcavities optically coupled to one another is highly sensitive, with regard to the achievable color rendering index and also the achievable efficiency of the OLED, to even very small layer thickness fluctuations during the deposition of the materials. Conventional vapor deposition methods for applying organic layers typically result for example in layer thickness fluctuations in a range of ±5%. As a result, an industrial scale realization of OLEDs having two microcavities optically coupled to one another (coupled-microcavity OLEDs) is possible only with very great difficulty.

Therefore, the problem addressed is that of overcoming this disadvantage and specifying a structure and a method enabling an industrial scale realization of OLEDs having two microcavities optically coupled to one another.

This problem is solved by means of an electronic component and a method for producing an electronic component as claimed in the independent patent claims.

Developments and advantageous configurations of the method for producing an optoelectronic semiconductor component and of the optoelectronic semiconductor component are specified in the dependent patent claims.

Various embodiments provide an electronic component, for example a light-emitting electronic component, and a method for producing an electronic component, for example a light-emitting electronic component, which ensures a reliably achievable high color rendering index comparable to a coupled-microcavity OLED and which also enables an industrial scale realization and production of such an electronic component.

Various embodiments provide an electronic component, for example a light-emitting electronic component. The electronic component may include a first electrode; an organic functional layer structure on or over the first electrode; a second electrode on or over the organic functional layer structure; a dielectric layer on or over the second electrode; and a reflection layer structure on or over the dielectric layer.

The dielectric layer provided in accordance with various embodiments instead of the second organic layer usually provided in a conventional coupled-microcavity OLED enables the dielectric layer to be applied more accurately with regard to the thickness of the dielectric layer applied. In accordance with various embodiments, the dielectric layer applied is not subject to the considerable layer thickness fluctuations described above, such as arise during the application of an organic layer. Consequently, in accordance with various embodiments, a more exact layer thickness control is achieved, whereby the achievable high color rendering index can be reliably ensured even in the case of an industrial scale realization.

Consequently, various embodiments clearly provide a coupled-microcavity OLED in which only one organic functional layer structure is provided and the latter is coupled, for example optically coupled, to a dielectric layer, thereby achieving the coupling effect for increasing the color rendering index.

Furthermore, it is pointed out that, in various embodiments, an encapsulation effect of the light-emitting electronic component formed is provided by the dielectric layer instead of the organic layer. In the case of a conventional coupled-microcavity OLED, it is usually necessary for the coupled-microcavity OLED formed also to be protected against oxygen and water by additional measures such as, for example, layers additionally applied on the coupled-microcavity OLED, for example ALD layers (ALD: atomic layer deposition), or a cavity glass encapsulation with a so-called getter.

Consequently, the use of the dielectric layer clearly provides a coupled-microcavity OLED structure in which the above-described problem of the layer thickness fluctuations is solved in conjunction with an encapsulation effect achieved at the same time. It should be pointed out that, in various embodiments, of course, additional layers or measures can also be provided, if desired, for additionally encapsulating the light-emitting electronic component.

In various embodiments, the expression “encapsulating” or “encapsulation” is understood to mean, for example, that a barrier against moisture and/or oxygen is provided, such that these substances cannot penetrate through the organic functional layer structure.

In one configuration, the second electrode may be designed in such a way that the dielectric layer is optically coupled to the organic functional layer structure.

Furthermore, the second electrode may be semitransparent with respect to the radiation emitted by the organic functional layer structure.

In one development, the dielectric layer is a layer which is transparent to radiation at least in a partial range of the wavelength range of 380 nm to 780 nm.

The dielectric layer may be a layer which is applied by means of one of the following methods: chemical vapor deposition (CVD) method; physical vapor deposition (PVD) method; spin coating method; printing; blade coating; spraying; and dip coating method.

In various embodiments, a plasma enhanced chemical vapor deposition (PE-CVD) method may be used as CVD method. In this case, a plasma may be generated in a volume above and/or around the element to which the layer to be applied is intended to be applied, wherein at least two gaseous starting compounds are fed to the volume and they are ionized in the plasma and excited to react with one another. The generation of the plasma may make it possible that the temperature to which the surface of the element is to be heated in order to make it possible to produce the dielectric layer, for example, may be decreased in comparison with a plasmaless CVD method. That may be advantageous, for example, if the element, for example the light-emitting electronic component to be formed, would be damaged at a temperature above a maximum temperature. The maximum temperature may be approximately 120° C. for example in the case of a light-emitting electronic component to be formed in accordance with various embodiments, such that the temperature at which the dielectric layer is applied, for example, may be less than or equal to 120° C. and, for example, less than or equal to 80° C.

Alternatively, the dielectric layer can be deposited by means of a physical vapor deposition (PVD) method, for example by means of sputtering, ion assisted deposition method or thermal evaporation.

In various configurations, the dielectric layer may be an atomic layer deposition layer, to put it another way a layer which has been applied by means of an atomic layer deposition (ALD) method.

An atomic layer deposition method can be understood to mean a method in which, in comparison with a different CVD method, firstly a first of at least two gaseous starting compounds is fed to a volume in which the element to whose surface the layer is intended to be applied by means of the ALD method is provided. The first starting compound can adsorb on the surface, for example regularly or irregularly (and then without long-range order). After the surface has been completely or virtually completely covered with the first starting compound, a second of the at least two starting compounds can be fed in. The second starting compound can react with the first starting compound adsorbed at the surface for example irregularly but for example in a manner completely covering the area, as a result of which a monolayer of the second layer can be formed. As in a different CVD method, provision can be made for heating the surface to a temperature above room temperature. As a result, the reaction for forming a monolayer can be initiated thermally. The surface temperature to be provided can depend on the starting materials, to put it another way on the first starting compound and the second starting compound. With repetition of these processes, a plurality of monolayers can thus be successively applied one on top of another, which makes possible a very accurate (reproducible) setting of the desired layer thickness of the layer to be applied by means of an ALD method.

The dielectric layer may have a layer thickness in a range of approximately 50 nm to approximately 2 μm, for example in a range of approximately 70 nm to approximately 200 nm.

The dielectric layer may include a material or a mixture of materials or a stack of layers of materials, for example Al₂O₃; ZrO₂; TiO₂; Ta₂O₅; SiO₂; ZnO; and/or HfO₂. This means that the dielectric layer may be formed for example by an individual layer composed of one material or a plurality of materials or from a plurality of layers stacked one above another and composed of the same or different materials, for example composed of materials such as have been described above. In principle, any suitable material/all suitable materials may be used which can be applied, for example can be deposited, with a sufficiently high accuracy with regard to the achievable layer thickness fluctuation.

A particularly high accuracy in the layer thickness control can be achieved with the use of an atomic layer deposition method for applying the dielectric layer, for which reason, for example, all materials which can be deposited by means of an atomic layer deposition method can be used, which is the case for the materials mentioned above.

With the use of an ALD method, in various embodiments the first starting compound and/or the second starting compound for the dielectric layer can be or contain organometallic compounds, for example trimethyl metal compounds and oxygen-containing compounds. By way of example, for the ALD deposition of the dielectric layer including Al₂O₃, it is possible to provide trimethylaluminum as first starting compound and water (H₂O) or N₂O as second starting compound. As an alternative thereto, it is possible to provide water (H₂O) or N₂O as first starting compound, for example.

In various embodiments, as a variant of an ALD method, a plasmaless ALD method (plasmaless atomic layer deposition, PLALD method) can be provided, for which no plasma is generated, rather in which, for forming the monolayers, the reaction of the abovementioned starting compounds is initiated only by means of the temperature of the surface to be coated. The temperature of the surface on which the layer is intended to be deposited can be greater than or equal to 60° C. and/or less than or equal to 120° C. in a PLALD method in various embodiments.

In various embodiments, as a variant of an ALD method, a plasma enhanced ALD method (plasma enhanced atomic layer deposition, PEALD method) may be provided, in which the second starting compound is fed in while a plasma is simultaneously generated, as a result of which, as in the case of a PECVD method, it can be possible that the second starting compound is excited. As a result, in comparison with a PLALD method, the temperature to which the surface is to be heated can be reduced and the reaction between the starting compounds can nevertheless be initiated by the generation of plasma. In this case, the monolayers can be applied for example at a temperature of less than 120° C. and, for example, less than or equal to 80° C. In order to produce further monolayers, the processes of feeding in the first starting compound and then feeding in the second starting compound can be repeated.

Various embodiments provide a method for producing an electronic component, for example a light-emitting electronic component. The method may include forming a first electrode; forming an organic functional layer structure on or over the first electrode; forming a second electrode on or over the organic functional layer structure; forming a dielectric layer on or over the second electrode; and forming a reflection layer structure on or over the dielectric layer.

The second electrode can be formed in such a way that the dielectric layer is optically coupled to the organic functional layer structure.

Furthermore, the second electrode may be formed as semitransparent with respect to the radiation emitted by the organic functional layer structure.

In one configuration, the dielectric layer may be formed as a layer which is transparent to radiation at least in a partial range of the wavelength range of 380 nm to 780 nm.

In another configuration, the dielectric layer may be formed by means of one of the following methods: chemical vapor deposition (CVD) method; physical vapor deposition (PVD) method; spin coating method; printing; blade coating; spraying; and dip coating method.

Furthermore, the dielectric layer may be applied by means of an atomic layer deposition method.

In accordance with another development, the dielectric layer may be formed with a layer thickness in a range of approximately 50 nm to approximately 2 μm, for example in a range of approximately 70 nm to approximately 200 nm.

In accordance with another development, the dielectric layer may be formed from a material or a mixture of materials or a stack of layers of materials, selected from a group consisting of: Al₂O₃; ZrO₂; TiO₂; Ta₂O₅; SiO₂; ZnO; and/or HfO₂.

Embodiments of the invention are illustrated in the figures and are explained in greater detail below.

In the figures:

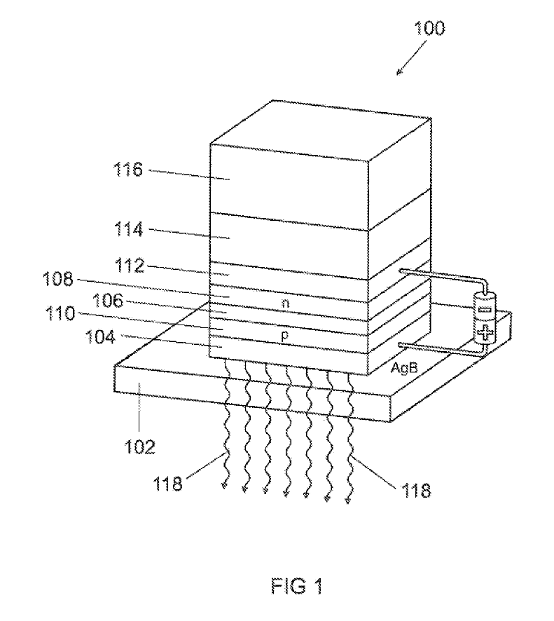

FIG. 1 shows a light-emitting electronic component in accordance with one embodiment; and

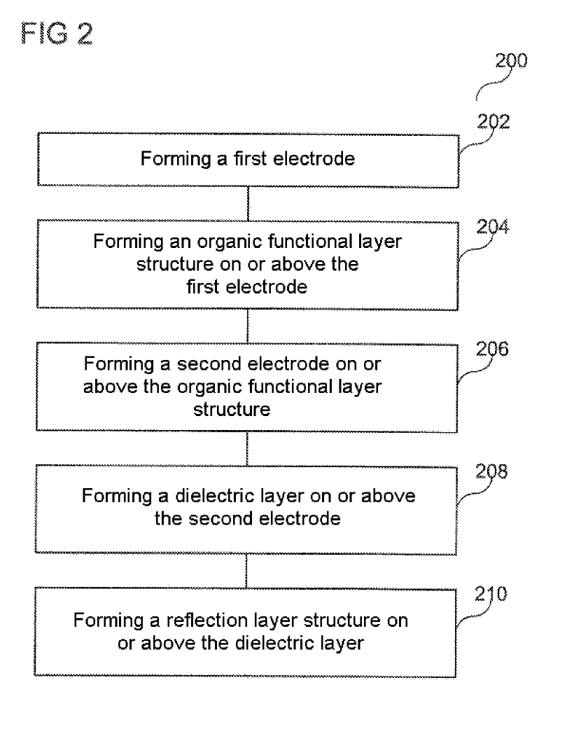

FIG. 2 shows a flowchart illustrating a method for producing a light-emitting electronic component in accordance with one embodiment.

In the following detailed description, reference is made to the accompanying drawings, which form part thereof and show, for illustration purposes, specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since components of embodiments can be positioned in a number of different orientations, the direction terminology serves for illustration purposes and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection, and a direct or indirect coupling. In the figures, identical or similar elements are provided with identical reference signs, insofar as this is expedient.

FIG. 1 shows an electronic component 100, for example a light-emitting electronic component 100, in accordance with various embodiments.

In various embodiments, the electronic component 100 can be embodied as an organic light-emitting diode (OLED), as an organic photodiode (OPD), as an organic solar cell (OSC), or as an organic transistor, for example as an organic thin film transistor (OTFT). In various embodiments, the light-emitting electronic component 100 can be part of an integrated circuit. Furthermore, a plurality of (for example light-emitting) electronic components 100 can be provided, for example in a manner accommodated in a common housing.

The (for example light-emitting) electronic component 100 can have a substrate 102. The substrate 102 can serve for example as a carrier element for electronic elements or layers, for example optoelectronic elements. By way of example, the substrate 102 may include or be formed from glass, quartz, and/or a semiconductor material or any other suitable material. Furthermore, the substrate 102 may include or be formed from a plastic film or a laminate including one or including a plurality of plastic films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). Furthermore, the substrate 102 may include for example a metal film, for example an aluminum film, a high-grade steel film, a copper film or a combination or a layer stack thereon. The substrate 102 may include one or more of the materials mentioned above. The substrate 102 can be embodied as transparent, partly transparent or else opaque.

A first electrode 104 may be applied on or over the substrate 102. The first electrode 104 (also designated hereinafter as bottom electrode 104) may be formed from or may be an electrically conductive material, such as, for example, a metal or a transparent conductive oxide (TCO) or a layer stack including a plurality of layers of the same or different metal or metals and/or the same or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs. Furthermore, the TCOs do not necessarily correspond to a stoichiometric composition and may furthermore be p-doped or n-doped. The first electrode 104 may be embodied as an anode, that is to say as a hole-injecting material.

In various embodiments, the first electrode 104 may be formed by a layer stack of a combination of a layer of a metal on a layer of a TCO, or vice versa. One example is a silver layer applied on an indium tin oxide layer (ITO) (Ag on ITO). In various embodiments, the first electrode 104 may include a metal (for example Ag, Pt, Au, Mg) or may include a metal alloy of the materials described (for example an AgMg alloy). In various embodiments, the first electrode 104 may include AlZnO or similar materials.

In various embodiments, the first electrode 104 may include a metal, which can serve for example as cathode material, that is to say as electron-injecting material. In various embodiments, inter alia for example Al, Ba, In, Ag, Au, Mg, Ca or Li and compounds, combinations or alloys of these materials may be provided as cathode material.

For the case where the light-emitting electronic component 100 is designed as a bottom emitter, the first electrode 104 may have for example a layer thickness of less than or equal to approximately 25 nm, for example a layer thickness of less than or equal to approximately 20 nm, for example a layer thickness of less than or equal to approximately 18 nm. Furthermore, the first electrode 104 may have for example a layer thickness of greater than or equal to approximately 10 nm, for example a layer thickness of greater than or equal to approximately 15 nm. In various embodiments, the first electrode 104 may have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

For the case where the light-emitting electronic component 100 is designed as a top emitter, then the first electrode 104 may have for example a layer thickness of greater than or equal to approximately 40 nm, for example a layer thickness of greater than or equal to approximately 50 nm.

Furthermore, the (for example light-emitting) electronic component 100 may have an organic functional layer structure 106, which has been or is applied on or over the first electrode 104.

The organic functional layer structure 106 may contain one or a plurality of emitter layers 108, for example including fluorescent and/or phosphorescent emitters, and one or a plurality of hole-conducting layers 110.

Examples of emitter materials which may be used in the electronic component in accordance with various embodiments in accordance with various embodiments for the emitter layer(s) 108 include organic or organometallic compounds such as derivatives of polyfluorene, polythiophene and polyphenylene (e.g. 2- or 2,5-substituted poly-p-phenylene vinylene) and metal complexes, for example iridium complexes such as the blue phosphorescent FIrPic (bis(3,5-difluoro-2-(2-pyridyl)phenyl-(2-carboxypyridyl)-iridium III), green phosphorescent Ir(ppy)₃ (tris(2-phenylpyridine)iridium III), red phosphorescent Ru (dtb-bpy)₃*2(PF₆)(tris[4,4′-di-tert-butyl-(2,2′)-bipyridine]ruthenium (III) complex) and blue fluorescent DPAVBi (4,4-bis[4-(di-p-tolylamino)styryl]biphenyl), green fluorescent TTPA (9,10-bis[N,N-di-(p-tolyl)-amino]anthracene) and red fluorescent DCM2 (4-dicyanomethylene)-2-methyl-6-julolidyl-9-enyl-4H-pryane) as non-polymeric emitters. Such non-polymeric emitters can be deposited by means of thermal evaporation, for example. Furthermore, it is possible to use polymer emitters, which can be deposited, in particular, by means of wet-chemical methods such as spin coating, for example.

The emitter materials may be embedded in a matrix material in a suitable manner.

The emitter materials of the emitter layer(s) 108 of the electronic component 100 may be selected for example such that the electronic component 100 emits white light. The emitter layer(s) 108 may include a plurality of emitter materials that emit in different colors (for example blue and yellow or blue, green and red); alternatively, the emitter layer(s) 108 can also be constructed from a plurality of partial layers, such as a blue fluorescent emitter layer 108 or blue phosphorescent emitter layer 108, a green phosphorescent emitter layer 108 and a red phosphorescent emitter layer 108. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic functional layer structure 106 may generally include one or a plurality of functional layers. The one or the plurality of functional layers may include organic polymers, organic oligomers, organic monomers, organic small, non-polymer molecules (“small molecules”) or a combination of these materials. By way of example, the organic functional layer structure 106 may include one or a plurality of functional layers embodied as a hole transport layer 110, such that to enable for example in the case of an OLED an effective hole injection into an electroluminescent layer or an electroluminescent region. By way of example, tertiary amines, carbazo derivatives, conductive polyaniline or polythylene dioxythiophene can be used as material for the hole transport layer 110. In various embodiments, the one or the plurality of functional layers can be embodied as an electroluminescent layer.

In various embodiments, the hole transport layer 110 may be applied, for example deposited, on or over the first electrode 104, and the emitter layer 108 can be applied, for example deposited, on or over the hole transport layer 110.

The electronic component 100 may generally include further organic functional layers that serve to further improve the functionality and thus the efficiency of the electronic component 100.

The light-emitting electronic component 100 may be embodied as a “bottom emitter” and/or a “top emitter”.

In various embodiments, the organic functional layer structure 106 may have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 106 can have for example a stack of a plurality of OLEDs arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 106 may have for example a stack of three or four OLEDs arranged directly one above another, in which case for example the organic functional layer structure 106 can may have a layer thickness of a maximum of approximately 3 μm.

A second electrode 112 may be applied on or over the organic functional layer structure 106.

The second electrode 112 may be designed in such a way that a dielectric layer 114 applied on or over the second electrode 112 is optically coupled to the organic functional layer structure 106. The second electrode 112 can be semitransparent with respect to the radiation emitted by the organic functional layer structure 106. In various embodiments, the second electrode 112 can have a layer thickness in such a way that a desired compromise is chosen between a sufficient coupling intensity between the organic functional layer structure 106 and the dielectric layer 114 (the larger the layer thickness of the second electrode 112, the lower the coupling intensity), and the achievable efficiency and thus the color rendering index of the light-emitting component 100 (the larger the layer thickness of the second electrode 112, the greater the efficiency). In various embodiments, the second electrode 112 may include or be formed from the same materials as the first electrode 104, metals being particularly suitable in various embodiments.

In various embodiments, the second electrode 112 may have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The dielectric layer 114 (also designated hereinafter as (transparent) intermediate layer) may have been or may be applied on or over the second electrode 112.

The dielectric layer 114 can be a layer which is transparent to radiation at least in a partial range of the wavelength range of 380 nm to 780 nm. For the case where for example a light-emitting monochrome or emission-spectrum-limited electronic component is intended to be provided, it suffices for the dielectric layer 114 to be transparent to radiation at least in a partial range of the wavelength range of the desired monochrome light or to the limited emission spectrum.

In various embodiments, the dielectric layer 114 is deposited by means of an ALD method, whereby the dielectric layer 114 is formed as an atomic layer deposition layer. In various embodiments, the dielectric layer 114 is deposited with a layer thickness in a range of approximately 50 nm to approximately 2 μm, for example in a range of approximately 70 nm to approximately 200 nm, for example in a range of approximately 100 nm to approximately 120 nm. In the case of these layer thicknesses, an encapsulation effect is ensured and the thickness of the coupled microcavity, for example, can be set very accurately. The dielectric layer 114 may include a material or a mixture of materials or a stack of layers of materials such as, for example, SiO₂; Si₃N₄; SiON (these materials are deposited, for example by means of a CVD method); Al₂O₃, ZrO₂; TiO₂; Ta₂O₅; SiO₂; ZnO; and/or HfO₂ (these materials are deposited for example by means of an ALD method); or a combination of these materials.

A reflection layer structure 116 may have been or may be applied on or over the dielectric layer 114.

The reflection layer structure 116 may be formed from the same materials as the first electrode 102, wherein the layer thickness may be chosen in such a way that, for the case where the light-emitting electronic component 100 is designed as a top emitter, the reflection layer structure 116 can have for example a layer thickness of less than or equal to approximately 25 nm, for example a layer thickness of less than or equal to approximately 20 nm, for example a layer thickness of less than or equal to approximately 18 nm. Furthermore, the first electrode 104 may have for example a layer thickness of greater than or equal to approximately 10 nm, for example a layer thickness of greater than or equal to approximately 15 nm. In various embodiments, the reflection layer structure 116 may have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

For the case where the light-emitting electronic component 100 is designed as a bottom emitter, then the reflection layer structure 116 may have for example a layer thickness of greater than or equal to approximately 40 nm, for example a layer thickness of greater than or equal to approximately 50 nm.

The reflection layer structure 116 may have one or a plurality of mirrors. If the reflection layer structure 116 has a plurality of mirrors, then the respective mirrors are separated from one another by means of a respective dielectric layer.

The light-emitting electronic component 100 illustrated in FIG. 1 is designed as a bottom emitter, as is symbolized by means of light beams 118.

With the aid of an ALD method and a CVD method when producing a light-emitting electronic component 100, the dielectric layer 114 may be deposited by means of an ALD method with a layer thickness that can be set very accurately. In various embodiments, the second organic layer provided in the conventional organic light-emitting diode having two microcavities optically coupled to one another is clearly replaced by one dense dielectric layer.

In various embodiments, the dielectric layer 114 applied has an encapsulation effect, such that the electronic component formed, and in this case for example the organic functional layer structure 106, is protected against penetration of air or water.

In a manner governed by technical dictates, the ALD method has a significantly smaller layer thickness fluctuation than vapor deposition of organic materials, as a result of which an industrial scale use of, for example, coupled-microcavity OLEDs is made possible in accordance with various embodiments. By way of example, this affords the possibility of also compensating for layer thickness fluctuations of the organic layers by means of the setting of the layer thickness of, for example, the dielectric layer 114, which can increase the yield in industrial scale installations.

In various embodiments, a lighting device or a display device may be provided having a plurality or multiplicity of light-emitting electronic components 100 in accordance with various embodiments. The lighting device or the display device may have an active luminous area embodied in a large-area fashion. In various embodiments, “in a large-area fashion” can mean that the luminous area has an area of greater than or equal to a few square millimeters, for example of greater than or equal to a few square centimeters, for example of greater than or equal to a few square decimeters.

FIG. 2 shows a flowchart 200 illustrating a method for producing a light-emitting electronic component in accordance with one embodiment.

In 202 a first electrode is formed and in 204 an organic functional layer structure is formed on or over the first electrode. Furthermore, in 206 a second electrode is formed on or over the organic functional layer structure, and in 208 a dielectric layer is formed on or over the second electrode. Finally, in 210 a reflection layer structure is formed on or over the dielectric layer.

1. An electronic component comprising:
a first electrode;
an organic functional layer structure on or over the first electrode;
a second electrode on or over the organic functional layer structure;
a dielectric layer on or over the second electrode, wherein the dielectric layer is applied by means of one of a chemical vapor deposition (CVD) method and a physical vapor deposition (PVD) method; and
a reflection layer structure on or over the dielectric layer,
wherein the organic functional layer structure forms a first microcavity between the first electrode and the second electrode, and the dielectric layer forms a second microcavity between the second electrode and the reflection layer structure.

2. The electronic component as claimed in claim 1,
wherein the second electrode is designed in such a way that the first microcavity is optically coupled to the second microcavity via the second electrode.

3. The electronic component as claimed in claim 2,
wherein the second electrode is semitransparent with respect to the radiation emitted by the organic functional layer structure.

4. The electronic component as claimed in claim 1,
wherein the dielectric layer is a layer which is transparent to radiation at least in a partial range of the wavelength range of 380 nm to 780 nm.

5. (canceled)

6. The electronic component as claimed in claim 1,
wherein the dielectric layer is an atomic layer deposition (ALD) layer.

7. The electronic component as claimed in claim 1,
wherein the dielectric layer has a layer thickness in a range of approximately 50 nm to approximately 2 μm.

8. The electronic component as claimed in claim 1,
wherein the dielectric layer comprises one of the group consisting of a material, a mixture of materials and a stack of layers of materials,
wherein the material selected from a group consisting of one or more of: SiO₂; Si₃N₄; SiON; Al₂O₃; ZrO₂; TiO₂;Ta₂O₅; SiO₂; ZnO; and HfO₂.

9. A method for producing an electronic component wherein the method comprises:
forming a first electrode;
forming an organic functional layer structure on or over the first electrode;
forming a second electrode on or over the organic functional layer structure;
forming a dielectric layer on or over the second electrode, wherein the dielectric layer is formed by means of one of a chemical vapor deposition method and a physical vapor deposition method; and
forming a reflection layer structure on or over the dielectric layer,
such that the organic functional layer structure forms a first microcavity between the first electrode and the second electrode, and
the dielectric layer forms a second microcavity between the second electrode and the reflection layer structure.

10. The method as claimed in claim 9,
wherein the second electrode is formed in such a way that the first microcavity is optically coupled to the second microcavity.

11. The method as claimed in claim 10,
wherein the second electrode is formed as semitransparent with respect to the radiation emitted by the organic functional layer structure.

12. The method as claimed in claim 9,
wherein the dielectric layer is formed as a layer which is transparent to radiation at least in a partial range of the wavelength range of 380 nm to 780 nm.

13. (canceled)

14. The method as claimed in claim 9,
wherein the dielectric layer is applied by means of an atomic layer deposition (ALD) method.

15. The method as claimed in claim 9,
wherein the dielectric layer is formed with a layer thickness in a range of approximately 50 nm to approximately 2 μm.

16. The method as claimed in claim 9,
wherein the dielectric layer comprised of a material, a mixture of materials and a stack of layers of materials,
wherein the material is selected from a group consisting of one or more of: SiO₂; Si₃N₄; SiON; Al₂O₃; ZrO₂; TiO₂; Ta₂0₅; SiO₂; ZnO; and HfO₂.
